(19) United States
(12) Patent Application Publication
(10) Pub. No.: US 2008/0130796 A1
(43) Pub. Date: Jun. 5, 2008

(54) Multi-Modulation Reception Method Based On Demodulation Of Signals From Modulations Whose Symbols Are Included In A Main Constellation

(75) Inventors: Alexandre Rouxel, Mathieu (FR); Damien Pouessel, Caen (FR)

Correspondence Address: WESTMAN CHAMPLIN & KELLY, P.A., SUITE 1400, 900 SECOND AVENUE SOUTH, MINNEAPOLIS, MN, 55402-3319, US

(73) Assignee: Wavecom, Issy-Les-Moulineaux Cedex (FR)

(21) Appl. No.: 10/587,908

(22) PCT Filed: Dec. 23, 2004
(86) PCT No.: PCT/FR04/03378

§ 371 Date: Jun. 18, 2007

(30) Foreign Application Priority Data
Jan. 30, 2004 (FR) 0400926

(51) Int. Cl. H03D 1/00; H04L 27/06; H04L 27/34; H04L 25/06

(52) U.S. Cl. 375/341

(57) ABSTRACT

The disclosure relates to a method for receiving a modulated signal according to a main constellation, known as a mail signal, and at least one signal which is modulated according to a second constellation, known as a second signal. The second constellation is included in the main constellation. The method comprises a demodulation stage for the main signal, which delivers reliability information, known as main reliability information, relating to the receipt of an element for each of the elements of the main constellation. Said method further comprises a determination stage for at least one element of the second constellation, at least one item of reliability information, known as second reliability information, relating to the reception of the element, based on main reliability information, in order to modulate the second signal.

### CROSS-REFERENCE TO RELATED APPLICATION

This Application is a Section 371 National Stage Application of International Application No. PCT/FR2004/003378, filed Dec. 23, 2004 and published as WO 2005/083964 on Sep. 9, 2005, not in English.

### FIELD OF THE DISCLOSURE

The field of the disclosure is signal processing applied to reception of signals and particularly radiocommunication signals.

More precisely, the disclosure relates to a method for receiving signals output from modulations for which the symbols are included in a set of symbols in a main constellation.

### BACKGROUND

1. Solutions According to Prior Art

The conventional reception technique used by receiving terminals that have to demodulate several signals output from different symbol constellations, has always consisted in installing one detector in each receiver for each different modulation to be processed.

2. Disadvantages of Prior Art

A first disadvantage of this state of prior art relates to the increase in the complexity of the terminal, particularly when used for integration of different detectors. Integration of such a plurality of detectors inside the receiving terminal necessarily involves an increase in the size of the terminal, and this increase is contrary to ergonomic and/or miniaturisation constraints of radio-communication terminals, for example of the mobile telephone type.

Another disadvantage of this state of prior art relates to the importance of design costs induced by such an increase in the complexity of the receiving terminal, and also the importance of costs and/or extra costs, associated with the corresponding additional induced tests and validation, and extra costs related to production. But competition on the radiocommunications market at the moment is such that even small savings in the design and/or manufacturing of terminals are sufficient to reduce the final selling price and increase market shares.

### SUMMARY

An embodiment of the present invention is directed to a method for reception of a signal modulated according to a main constellation, called the main signal, and at least one signal modulated according to a secondary constellation, called the secondary signal. The secondary constellation is included in the main constellation. The method comprises a demodulation step of the main signal, outputting an information of confidence for each of the elements in the main constellation, related to reception of each element, called the main confidence information.

According to an embodiment of the invention, such a method advantageously comprises a step to determine at least one information of confidence related to reception of one element of the secondary constellation, called secondary information of confidence, using at least one of the main information of confidence so as to demodulate the secondary signal.

Thus, an embodiment of the invention is based on a new and inventive approach to demodulation of signals output from different modulations, but for which the symbols are included in a set of symbols of a main constellation.

Preferably, the element is one of the bits transmitted by a symbol in the main and/or secondary constellation.

Advantageously, in a second embodiment, the main confidence bit (or information of confidence) is a hard decision reception of the bit in the main signal. This hard decision is output from a hard outputs (also called hard decisions) detector that does not output soft bits directly.

The method according to an embodiment of the invention preferably comprises a prior step to determine the log likelihood ratio (LLR) of the bit called “soft bit”, for at least some of the bits of the main signal, using the associated hard decision.

Preferably, the prior determination step uses a criterion belonging to the group comprising:
the Lop-Map criterion;
the Max-Log-Map criterion;
the SOVA (Soft-Output Viterbi Algorithm based on the maximum likelihood criterion for detection of the most probable sequence).

It can also non-restrictively use an approximation of one of these criteria.

Advantageously, the main and/or secondary confidence bit associated with a bit is a log likelihood ratio (LLR) of the bit, called the main and/or secondary soft bit.

Also advantageously, the step to determine the secondary confidence bit comprises the following sub-steps:
the secondary “soft bits” are expressed as a function of a posteriori probabilities of symbols in the secondary constellation, the symbols in the secondary constellation also belonging to the main constellation, so as to obtain a first expression;
the a posteriori probabilities of bits in the main constellation are expressed as a function of the a posteriori probabilities of symbols in the main constellation, bringing out the soft bits in the main constellation, output during the demodulation step of the main signal so as to obtain a second expression.

The method according to an embodiment of the invention also preferably comprises a sub-step for mathematical simplification of the first expression, using a saturated linear approximation or a piecewise linear approximation.

Advantageously, the method according to an embodiment of the invention also comprises a sub-step to classify symbols in the main constellation so as to minimise the number of soft bits in the main constellation used during the calculation of soft bits in the secondary constellation. Such a sub-step can optimise the calculation of the expression (4) described below for the first embodiment of the invention, by maximising the number of αᵢ″ values equal to zero.

In one variant of the method, the element is advantageously a symbol in the main and/or secondary constellation.

Preferably, the main and/or secondary confidence bit associated with a symbol is an a posteriori probability of a symbol in said main and/or secondary constellation.

During the main signal demodulation step, the main confidence bits are preferably calculated using one of the detection algorithms belonging to the group comprising:
the Max-Log-Map;
the Log-Map;
SOVA (Soft-Output Viterbi Algorithm based on the maximum likelihood criterion for detection of the most probable sequence);
DDFSE (Delayed Decision Feedback Sequence Estimation);
RSSE (Reduced-State Sequence Estimation);
M-algorithm;
T-algorithm.

Advantageously, since the detection algorithm is two-directional, the secondary confidence bits associated with the symbols in the secondary constellation are secondary soft bits corresponding to the log likelihood ratio (LLR) values of symbol bits, and are determined by the following sub-steps:
select a sub-set of a posteriori probabilities of symbols in the secondary constellation among the set of a posteriori probabilities of available symbols in the main constellation;
determine secondary soft bits as a function of the sub-set of a posteriori probabilities of symbols in the secondary constellation, the symbols in the secondary constellation also belonging to the main constellation.

Furthermore, the prior determination sub-step uses a criterion preferably belonging to the following group:
the Log-Map criterion;
the Max-Log-Map criterion;
SOVA (Soft-Output Viterbi Algorithm based on the maximum likelihood criterion for detection of the most probable sequence).

An approximation of one of these criteria can also be used in this determination sub-step.

Since the detection algorithm is single-directional, secondary confidence bits associated with symbols in the secondary constellation are advantageously secondary soft bits corresponding to the log likelihood ratio (LLR) values of symbol bits and are determined by the following sub-steps:
select a sub-set of a posteriori probabilities of symbols in the secondary constellation among the set of a posteriori probabilities of available symbols in the main constellation;
determine secondary soft bits as a function of the sub-set of a posteriori probabilities of symbols in the secondary constellation, the symbols in the secondary constellation also belonging to the main constellation;
determine the sign of secondary soft bits as a function of the value of bits of symbols in the main constellation.

Preferably, the main and/or secondary constellations belong to the group comprising:
M-QAM modulations, where M=2^{m}
N-PSK modulations, where N=2ⁿ (particularly QPSK and BPSK);
the linearised GMSK or MSK modulation.

An embodiment of the invention also advantageously relates to a receiving terminal of one modulated signal according to a main constellation, called the main signal, and at least one modulated signal according to a secondary constellation, called the secondary signal. The secondary constellation is included in the main constellation and the receiver comprising means of demodulating the main signal outputting a confidence bit related to reception of each element in the main constellation, called the main confidence bit. Such a receiver also advantageously comprises means of determining at least one confidence bit related to reception of at least one element in the secondary constellation, called the secondary confidence bit, using at least one of the main confidence bits, so as to demodulate the secondary signal.

Such a receiver advantageously uses a method for receiving a signal according an embodiment of to the invention, this signal being modulated according to a main constellation, and called the main signal, and for receiving at least one signal modulated according to a secondary constellation and called the secondary signal.

Other characteristics and advantages will become clearer after reading the following description of a preferred embodiment given as a simple illustrative and non-limitative example and the attached drawings.

### BRIEF DESCRIPTION OF THE DRAWINGS

FIGS. 1.a and 1.b show a block diagram of the method according to an embodiment of the invention, either by recombination of soft bits (FIG. 1.a) or by recombination of a posteriori probabilities (FIG. 1.b);

FIG. 2 gives an illustration of the constellation associated with an 8-PSK modulation used in an EDGE system;

FIG. 3 gives an illustration of the binary signal coding of the 8PSK EDGE as the main modulation and of a QPSK sub-constellation.

### DETAILED DESCRIPTION OF ILLUSTRATIVE EMBODIMENTS

The general principle of an embodiment of the invention is based on demodulation of signals output from modulations in which symbols are included in a main constellation, by reusing a detector for which the previous initial function was solely to demodulate signals output from the modulation of all symbols in the main constellation.

Three embodiments of the method are used to perform such processing, as presented in the remainder of this document.

A first embodiment of the method consists of recombining confidence bits (soft bits) that can be in the form of log likelihood ratios (LLR), calculated on bits of symbols output from detection of the main modulation to deduce the soft bits of a sub-constellation. Depending on the case, such a recombination step of soft bits may or may not generate the loss of information, or may require prior simplification in order to facilitate implementation of the calculation of soft bits of the sub-constellation.

This first embodiment of the method based on the recombination of soft bits is exemplified through the use of a GSM/GPRS/EDGE type receiver that uses an 8-PSK (8-Phase Shift Keying) type detector to demodulate GMSK (Gaussian Minimum Shift Keying) type signals without approximation and for which the complexity then becomes very low.

Remember the meaning of the acronyms mentioned above, which will be repeated throughout the remainder of the description.

The EDGE (Enhanced Data rate through GSM Evolution) system based on the 8-PSK modulation is the system replacing the GSM (Global System for Mobile Communication) system based on GMSK modulation.

In a second embodiment, applied to the use of hard decision detectors (or outputs), steps to reconstruct the soft bits are introduced and enrich steps used in the first proposed embodiment.

The third proposed embodiment relates to the use of reprogrammable generic detectors for which the method no longer operates on soft bits but on a posteriori probabilities (APP) of symbols in the main constellation. Two generic architectures, one adapted to single-directional algorithms, and the other to two-directional algorithms, can be used for the second embodiment of the method. They are described in section 7.3 in this document.

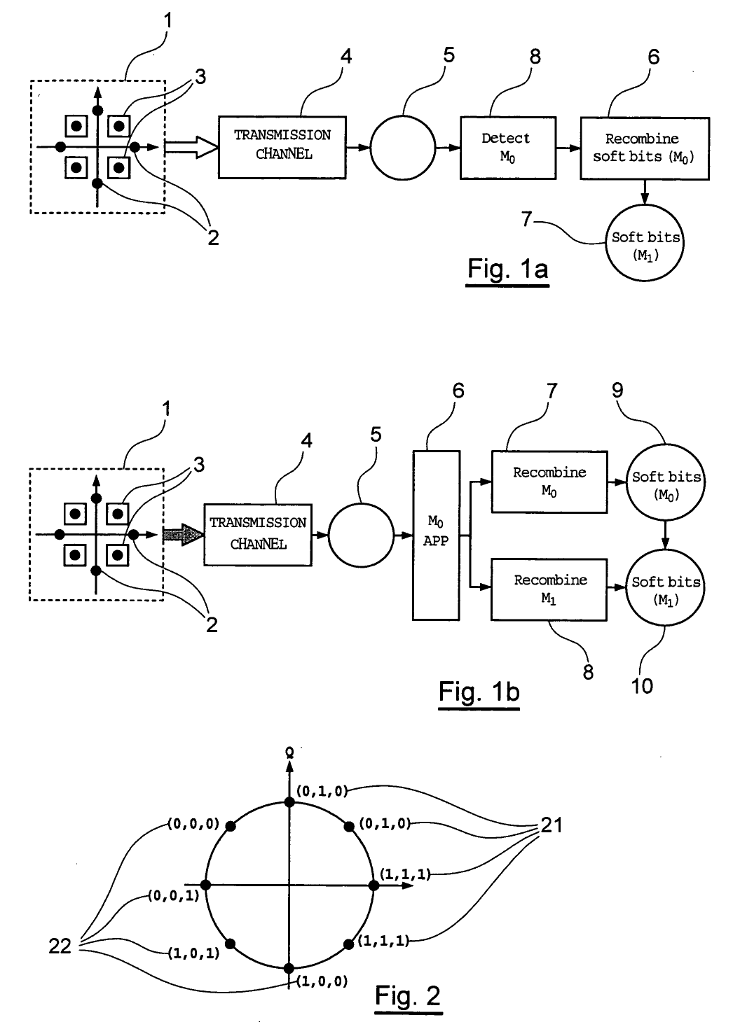

We will describe three embodiments with reference to FIGS. 1.a, 1.b, 2 and 3.

### Description of a First Embodiment by Recombination of Soft Bits of a Detector with Soft Outputs

In this first embodiment, the method is applicable to the case in which the receiver comprises a detector with soft outputs with the function of demodulating a signal belonging to a first main constellation and that must be reused without any modification to detect a signal (that we will subsequently call a secondary signal) belonging to a sub-constellation of the main constellation. The main constellation contains a predetermined set of a finite number of symbols (N>0), and therefore the sub-constellation contains a predetermined sub-set of a finite number of symbols (n≦N).

In this first embodiment, the method is described in the case of demodulation of a secondary signal output from a modulation for which symbols belong to a sub-constellation of a main constellation. However, the method described may easily be generalised to the case of detection of several secondary signals belonging to several sub-constellations of the main constellation, by reuse of the detector initially designed to demodulate the signal from the main constellation.

We use the FIG. 1.a to present and describe the method according to the first embodiment, and in this case we consider emission (1) of two modulation constellations M0 (2) and M1 (3) such that M1 (3) (sub-constellation) is included in M0 (2) (main constellation). The number of bits transmitted per symbol in modulation M0 will then be called m₀ and the number of bits transmitted per symbol in modulation M1 will be called m₀.

The main constellation M0 then contains 2^{m0} symbols and sub-constellation M1 contains 2^{m1} symbols, where (m₁<m₀).

A so-called confidence bit is used to demodulate the signal output from modulation M1. In this case it corresponds to a log likelihood ratio (LLR) or an approximation of this logarithm, in other words a logarithm of the probability that a bit (that can only be equal to two values, either 0 or 1) of a symbol emitted from M0 actually corresponds to 0 or 1 when it is received. This confidence bit is calculated in the form of log likelihood ratio (LLR) called the main and/or secondary soft bit, for each of the bits in symbols in M0 and/or M1.

In this first embodiment, the method is broken down in the following three main steps necessary to determine the confidence bit related to the value of bits received through the transmission channel (4) for symbols belonging to sub-constellation M1 (3) (secondary soft bits) using the soft bits associated with symbols in the main modulation (2);
Step 1: secondary soft bits are expressed as a function of a posteriori probabilities of symbols in secondary constellation M1 (also belonging to the main constellation M0) so as to obtain a first expression giving a recursive formulation of the LLR of the secondary modulation M1 as a function of the LLR values of the main modulation M0;
Step 2: if necessary, the expression obtained in step 1 is mathematically simplified using an approximation in the form of a function f(.) written in the form f(x)=log(1+e^{x});
Step 3: the a posteriori probabilities of detected bits (8) in the main constellation M0 are expressed as a function of a posteriori probabilities of symbols in the main constellation M0, including soft bits of the main constellation that are output in the preliminary demodulation step (5) of the main signal.

These three steps are described in more detail below.

### Step 1:

This step consists of writing log likelihood ratios (LLR), in other words soft bits for each bit of symbols belonging to a sub-constellation M1.

The LLR of m₀ bits associated with the main modulation M0, assumed to be known and calculated by the detector that is required to be reused here, are denoted X₀ . . . Xₘ_{₀}₋₁.

Similarly, the LLR values of m₁ bits associated with the secondary modulation M1 that is to be expressed as a function of bits X₀ . . . Xₘ_{₀}₋₁ calculated by the detector and assumed to be known, are denoted Y₀ . . . Yₘ_{₁}₋₁.

Eₖ denotes all indexes of symbols in sub-constellation M1 for which the bit with index k that depends on the binary signal coding, is equal to 0 and its complement in the main constellation M0 is denoted C_{M}_{₀}(Eₖ).

Note also that conventionally, the a posteriori probability of a symbol Sᵢ is denoted P(Sᵢ) and the LLR of the bit with index k associated with the secondary modulation M1 is denoted as follows:

$${Y}_{k} = log \frac{{\sum }_{i ∈ {E}_{k}} P ( {S}_{i} )}{{\sum }_{i ∈ {C}_{{M}_{1}} ( {E}_{k} )} P ( {S}_{i} )} \qquad ( 1 )$$

It then becomes possible to reindex the symbols such that the indexes varying from 0 to M₁/2−1 are associated with the symbols for which the bit with index k is equal to 0 and indexes from M₁/2 to (M₁−1) are associated with symbols for which the bit with index k is equal to 1. Therefore expression (1) can be rewritten as follows:

$${Y}_{k} = log \frac{{\sum }_{i = 0}^{{M}_{1} / ( 2 - 1 )} P ( {S}_{i} )}{{\sum }_{i = {M}_{1} / 2}^{{M}_{1} - 1} P ( {S}_{i} )} \qquad ( 2 )$$

### Step 2:

This step consists of simplifying writing of equation (2) by introducing the above mentioned function f(x)=log(1+e^{x}).

Therefore, after the function f(.) has been introduced, expression (2) can be written in the form of a recursive formulation of the LLR of the secondary modulation M1 as a function of the LLR values of the main modulation M0:

$${Y}_{k} = log \frac{P ( {S}_{0} )}{P ( {S}_{{M}_{1} / 2} )} + f ( log \frac{P ( {S}_{1} )}{P ( {S}_{0} )} + f ( log \frac{P ( {S}_{2} )}{P ( {S}_{1} )} … + f ( log \frac{P ( {S}_{{M}_{1} / 2 - 1} )}{P ( {S}_{{M}_{1} / 2 - 2} )} ) … ) ) - f ( log \frac{P ( {S}_{{M}_{1} / 2 + 1} )}{P ( {S}_{{M}_{1} / 2} )} … + f ( log \frac{P ( {S}_{{M}_{2} / 2 + 2} )}{P ( {S}_{{M}_{1} / 2 + 1} )} … + f ( log \frac{P ( {S}_{{M}_{1}} )}{P ( {S}_{{S}_{{M}_{1} - 1}} )} ) … ) \qquad ( 3 )$$

Thus, as an illustrative example, assuming that the number m₁ of bits associated with the secondary modulation M1 that is to be expressed as a function of the bits of symbols in the main constellation, is equal to 3, the result is an expression of Y_{K} written as follows:

$${Y}_{k} = log \frac{P ( {S}_{0} ) + P ( {S}_{1} ) + P ( {S}_{2} ) + P ( {S}_{3} )}{P ( {S}_{4} ) + P ( {S}_{5} ) + P ( {S}_{6} ) + P ( {S}_{7} )}$$

which can be written as follows based on the simplification obtained by introduction of the function f(.):

$${Y}_{k} = log \frac{P ( {S}_{0} )}{P ( {S}_{4} )} + f ( log \frac{P ( {S}_{1} )}{P ( {S}_{0} )} + f ( log \frac{P ( {S}_{2} )}{P ( {S}_{1} )} + f ( log \frac{P ( {S}_{3} )}{P ( {S}_{2} )} ) ) ) - f ( log \frac{P ( {S}_{5} )}{P ( {S}_{4} )} + f ( log \frac{P ( {S}_{6} )}{P ( {S}_{5} )} + f ( log \frac{P ( {S}_{7} )}{P ( {S}_{6} )} ) ) )$$

Depending on the case and the required degree of simplification, the function f(.) used will be either tabulated or simplified. For a simplified function, the function f(.) may non-limitatively be either a saturated linear type function or a piecewise linear function.

In the case of a saturated linear function, the function f(.) is then written in the following conditional form:

f(x)=x, if x>0

f(x)=0 otherwise.

In the case of a piecewise linear function, the function f(.) corresponds to a more complex shaped approximation, that has the advantage that it can use a straight line for which the slope is determined by a division by two, in other words all bits are offset by one towards the right. It is then written in the following form:

$$\begin{matrix}S = log ( 2 ) / 2 & \\ f ( x ) = x & if x > S \\ f ( x ) = \frac{x}{2} + log ( 2 ) & if - S \leq x \leq S \\ f ( x ) = 0 & if x < - S\end{matrix}$$

### Step 3:

Thus, since bits of symbols are transmitted independently, it becomes possible to write the LLRs between symbols present in expression (3) above including the values Xᵢ of the corresponding LLR values of the m₀ bits associated with the main modulation M0, which are actually calculated by the receiver detector, one essential role of which is normally to process only symbols output from a single predetermined main constellation.

Therefore each LLR between symbols present in expression (3) can be written in the following developed form:

$$P ( {S}_{i} ) = {\prod }_{k = 0}^{k = {m}_{0} - 1} P ( {b}_{k} ( {S}_{i} ) )$$

where bₖ(Sᵢ) corresponds to the bit with index k in symbol Sᵢ belonging to the set of symbols in the main constellation M0.

This developed expression of each of the soft bits (LLR) associated with symbols (secondary symbols) in the sub-constellation M1 also contained in the set of symbols in the main constellation M0, is used to include values of Xᵢ (for index i varying from 0 to m₀−1) actually calculated by the detector (6), in the expression of the secondary soft bits (7). Each of the terms in the logarithm included in expression (3) and used to calculate Yₖ values, where k is between 0 and m₁−1), can then be replaced as follows:

$$log \frac{P ( {S}_{n + 1} )}{P ( {S}_{n} )} = {\sum }_{i = 0}^{{m}_{0} - 1} {α}_{i}^{n} \cdot {X}_{i} \\ where {α}_{i}^{n} ∈ \{ - 1 , 0 , 1 \} \qquad ( 4 )$$

In one implementation phase of the method in a receiving terminal that is based on this first described embodiment, it is important to emphasize that a further simplification could be made simply by judicious choices of the expressions.

In particular, a sub-step will be introduced to minimise the Hamming distance between symbols in the main constellation, to simplify the formulation and calculation of the expression (4).

Indeed, formula (3) is not unique and its calculation depends particularly on the manner in which the different symbols in the main constellation are indexed. It is then possible to put symbols into order such that the number of terms αᵢ not equal to zero in formula (4) is minimised, which is therefore equivalent to minimising the Hamming distance between each symbol Sᵢ and symbols Sᵢ₊₁.

When the bits transmitted by the symbols in sub-constellation M1 form a part of the bits of the symbols in the main constellation M0, at least one value αᵢ in expression (4) is equal to zero.

Therefore all that is necessary to further minimise the number of values αᵢ=0 is to put the symbols into order so as to minimise the Hamming distance between each symbol and its neighbours after it and before it.

Consider the example in which m₀=4 (where m₀ is equal to the number of bits transmitted per symbol in modulation M0) and m₁=3 (where m₁ is equal to the number of bits transmitted per symbol in modulation M1). Therefore, symbols with indexes S₀, S₁, S₂, S₃ have at least one bit in common, which means that their Hamming distance is less than m₀−1=3. In this case, there are four symbols all coded on 4 bits, and all having a fixed bit in common.

There are then three available freedom bits that are then used in calculations to put the symbols into more optimum order.

This simplification technique based on the calculation of the Hamming distance between symbols is useful for designing binary signal coding, specifying firstly the emission and secondly minimising the complexity of the receiver re-using the main modulation detector.

We will now present simple illustrative and non-limitative examples of two cases using the first embodiment of the method.

### Example No. 1

Consider the example in which m₁=1 (m₁ is the number of bits transmitted per symbol in modulation M1), therefore M1 is a sub-constellation with two states which can therefore be written directly in the form of a combination of Xᵢ, in other words soft bits (LLR) of symbols in the main constellation. Therefore, in this case there is no need to perform the simplification step mentioned above using the function ƒ(.).

This example corresponds to a description of the constellations in the case of GMSK/8-PSK modulations.

The GMSK modulation in the GSM/GPRS/EDGE standard may be approximated by a BPSK modulation with a π/2 offset filtered by the EDGE emission filter. Once the offset has been eliminated by deoffsetting, the possible emitted symbols are then equal to the values +1/−1.

As shown in FIG. 2, the two symbols +1/−1 will also be elements of the alphabet (21, 22) of the 8-PSK modulation used in the EDGE system.

All that is necessary to calculate the confidence bit in the form of log likelihood ratios (LLR) of GMSK symbols at the output from a 8-PSK detector is to write LLR values associated with the GMSK modulation symbols as follows:

$$\begin{matrix}{Y}_{0} = log \frac{P ( + 1 )}{P ( - 1 )} \\ = log \frac{{P}_{0} ( 1 ) {P}_{1} ( 1 ) {P}_{2} ( 1 )}{{P}_{0} ( 0 ) {P}_{1} ( 0 ) {P}_{2} ( 1 )} \\ = log ( \frac{{P}_{0} ( 1 )}{{P}_{0} ( 0 )} ) + log ( \frac{{P}_{1} ( 1 )}{{P}_{0} ( 0 )} )\end{matrix}$$

where
P(+1) is the a posteriori probability (APP) of the +1 symbol;
P(−1) is the a posteriori probability (APP) of the −1 symbol;
Pᵢ(1) is the a posteriori probability (APP) that bit i, where 0≦i≦m₀, is equal to 1;
Pᵢ(0) is the a posteriori probability (APP) that bit i, where 0≦i≦m₀, is equal to 0.

We can then deduce that Y₀=−(X₀+X₁).

Therefore this means that with no approximation, the soft bit of the GMSK modulation is written as the sum of soft bits with index (3 k) and (3 k+1) of the 8-PSK modulation, with changed sign.

Therefore the method to recombine soft bits is particularly simple when it is applied to the linearised GMSK modulation. Furthermore, it does not make any assumption about the manner in which soft bits are calculated by the 8-PSK detector which makes it generic and independent.

### Example No. 2

### Case of an OPSK Type Secondary Modulation Transmitted on an EDGE Type Main Constellation

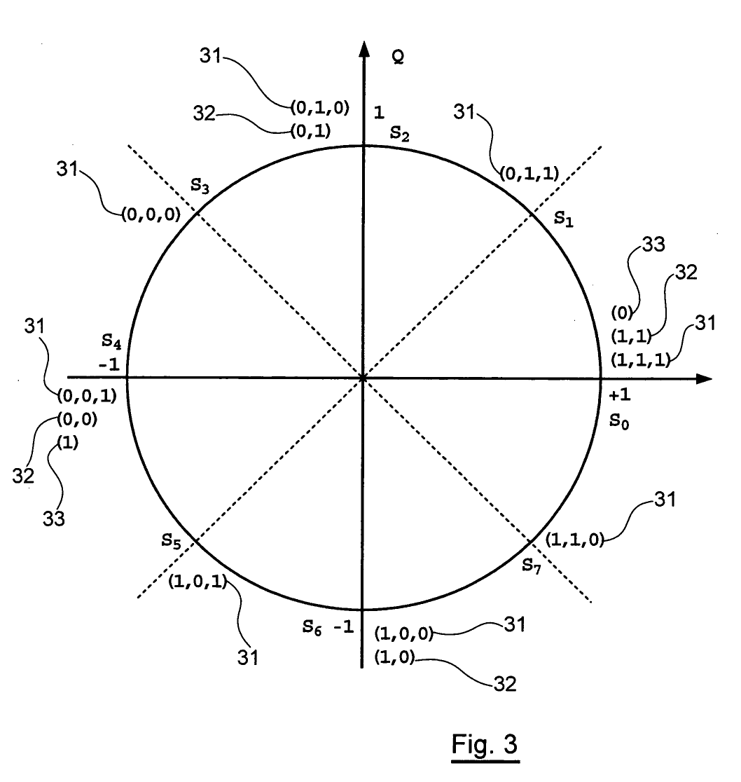

This new example shown in FIG. 3 shows the most complex case of an EDGE type 8 PSK main modulation (31) and a QPSK (quadrature Phase Shift keying) type secondary modulation 32 and a GMSK type secondary modulation 33. The corresponding binary signal coding of the symbols are given and are listed in the corresponding table given below:

| Symbol | Binary code |
|---|---|
| S₀ | (1, 1, 1) |
| S₁ | (0, 1, 1) |
| S₂ | (0, 1, 0) |
| S₃ | (0, 0, 0) |
| S₄ | (0, 0, 1) |
| S₅ | (1, 0, 1) |
| S₆ | (1, 0, 0) |
| S₇ | (1, 1, 0) |

Expression (3) mentioned above is used to write the LLR values Y₀ and Y₁ for m₁=2 bits associated with the QPSK secondary modulation 32 as follows:

$$\begin{matrix}{Y}_{0} = log \frac{P ( {S}_{2} ) + P ( {S}_{4} )}{P ( {S}_{0} ) + P ( {S}_{6} )} \\ = log \frac{P ( {S}_{2} )}{P ( {S}_{0} )} + log ( 1 + \frac{P ( {S}_{4} )}{P ( {S}_{2} )} ) - log ( 1 + \frac{P ( {S}_{6} )}{P ( {S}_{0} )} )\end{matrix}$$

$$and$$

$$\begin{matrix}{Y}_{1} = log \frac{P ( {S}_{4} ) + P ( {S}_{6} )}{P ( {S}_{0} ) + P ( {S}_{2} )} \\ = log \frac{P ( {S}_{4} )}{P ( {S}_{0} )} + log ( 1 + \frac{P ( {S}_{6} )}{P ( {S}_{4} )} ) - log ( 1 + \frac{P ( {S}_{2} )}{P ( {S}_{0} )} )\end{matrix}$$

The result after simplification by function f(.) is as follows:

Y₀=X₀+X₂+ƒ(X₁−X₂)−ƒ(X₁+X₂)

Y₁=X₀+X₁+ƒ(−X₀+X₂)−ƒ(X₀+X₂)

The next step is to apply one of the above-mentioned methods to simplify the expressions of Y₀ and Y₁ obtained. The f(.) function used may then be either in the form of a saturated linear type function or a piecewise linear function.

### Simplification Number 1: Application of the Saturated Linear Function f(.).

In the case of a saturated linear function, the first step to calculate the first soft bit Y₀ associated with the QPSK secondary modulation consists of calculating the following quantities:

S₀=X₁−X₂

S₁=X₁+X₂

Depending on the result of the comparisons of S₀ and S₁ with 0, the secondary soft bit Y₀ of the QPSK modulation is then expressed as being one of the relations given in the following table, which expresses the value of the soft bit Y₀ as a function of the “soft bits” calculated by the 8PSK main modulation detector:

| | S₀ ≦ 0 | S₀ > 0 |
|---|---|---|
| S₁ ≦ 0 | Y₀ = X₀ + X₂ | Y₀ = X₀ + X₁ |
| S₁ > 0 | Y₀ = X₀ − X₁ | Y₀ = X₀ − X₂ |

Similarly, the following quantities are calculated so that the second soft bit Y₁ associated with the QPSK secondary modulation can be calculated:

S₂=X₂−X₀

S₃=X₂+X₀

Depending on the result of the comparisons of S₂ and S₃ with 0, the secondary soft bit Y₁ of the QPSK modulation is then expressed as being one of the relations given in the following table, which expresses the value of the soft bit Y₁ as a function of the soft bits calculated by the 8PSK main modulation detector:

| | S₂ ≦ 0 | S₂ > 0 |
|---|---|---|
| S₃ ≦ 0 | Y₁ = X₀ + X₁ | Y₁ = X₁ + X₂ |
| S₃ > 0 | Y₁ = X₁ − X₂ | Y₁ = X₁ − X₀ |

### Simplification No. 2: Application of the Most Complex Approximation f(.) Called Piecewise Linear Approximation (Saturated).

If a piecewise linear function (saturated) is applied, the first step also consists in calculating the four sums S₀, S₁, S₂ and S₃.

The next step is then to compare the four sums with the +S and −S thresholds calculated as follows:

$$S = \frac{log ( 2 )}{2} .$$

In this case, the corresponding values of the QPSK secondary modulation bits Y₀ and Y₁ are then deduced, as summarised in the following table for the soft bit Y₀ expressed as a function of soft bits Xᵢ actually calculated by the 8PSK detector:

| | S₀ < −S | −S ≦ S₀ ≦ S | S₀ > S |
|---|---|---|---|
| S₁ < −S | Y₀ = X₀ + X₂ | ${Y}_{0} = \frac{{X}_{2} + {X}_{1}}{2} + \\ {X}_{0} + 2 S$ | Y₀ = X₀ + X₁ |
| −S ≦S₁ ≦ S | ${Y}_{0} = \frac{{X}_{2} - {X}_{1}}{2} + \\ {X}_{0} - 2 S$ | Y₀ = X₀ | ${Y}_{0} = \frac{- {X}_{2} + {X}_{1}}{2} + \\ {X}_{0} - 2 S$ |
| S₁ > S | Y₀ = X₀ − X₁ | ${Y}_{0} = \frac{- {X}_{2} - {X}_{1}}{2} + \\ {X}_{0} + 2 S$ | Y₀ = X₀ − X₂ |

### Description of a Second Embodiment

### Case of Detectors with Hard Outputs

In the second embodiment, the method in the first embodiment is enriched by performing two new steps before the above mentioned three steps related to the first embodiment, so as to provide it with the capability of extracting and using soft bits from the bits of a sub-constellation, even if the detector used for the main modulation only outputs hard bits.

These two new steps shown in FIG. 1.b are characteristics of the second embodiment of the method. They concern the following respectively:
reconstruction (6) of the soft bits of the main modulation using a Log-Map type criterion or a Max-Log-Map type criterion;
recombination of the reconstructed soft bits of M0 (9) to obtain soft bits of the sub-constellation M1 (10).

We will now describe the step to reconstruct soft bits of the main modulation.

The detector used only outputs hard bits (or symbols) denoted S and composed of a number m₀ of bits bᵢ(S) for 0≦i≦m₀. Starting from hard decisions and the binary signal code of the main constellation assumed to be known, it then becomes possible to reconstitute a soft bit Xₖ for each of the m₀ bits bᵢ(S) of the hard symbol S. This reconstruction of each soft bit Xₖ in the main constellation uses the Max-Log-Map type criterion and then consists of the following additional steps:

a) search for the symbol in the main constellation that minimises the distance from the hard symbol S and with a bit at position k characterised in that it is the complement of bₖ(S);

b) calculate the distance between the symbol selected in step a) and the hard symbol S;

c) assign a positive or a negative sign to the distance calculated in the step b) as a function of the value of bₖ (S).

It is important to note that this reconstruction function is implemented very simply using a table containing m₀ distances for each symbol in the main constellation, related to the 2^{m}^{₀} bits of the symbols in this main constellation. This table is directly addressed by the value of the hard symbol S. Therefore it comprises m₀*2^{m}^{₀} elements.

The Log-Map criterion can also be used in the preliminary reconstruction step of the soft bits. It is used in the same way as the Max-Log-Map criterion. The only difference in the use of one or the other of these two criteria is based on the fact that all symbols in the main constellation, for which the position bit k is the complement of bₖ(S) of the hard symbol S, are used in the calculation of Xₖ, in other words in the calculation of the reconstructed soft bits of the main constellation. Implementation of this second method based on the Log-Map-Criterion then also uses a table comprising m₀*2^{m}^{₀} elements, which is addressed in the same way as for use of the Max-Log-Map criterion.

The purpose of the second preliminary step characteristic of this second embodiment of the method is to enable recombination of the soft bits of the main constellation so as to determine the soft bits Yₖ of a sub-modulation.

This recombination step is based particularly on the following successive steps 1 to 3 identical to the steps described above in the section related to the first embodiment of the method:
Step 1: the secondary soft bits are expressed as a function of a posteriori probabilities of symbols in the secondary constellation M1 (also belonging to the main constellation M0) so as to obtain a first expression giving a recursive formulation of the LLR of the secondary modulation M1 as a function of the LLR values of the main modulation M0;
Step 2: the expression obtained in step 1 is mathematically simplified if necessary using an approximation in the form of a function f(.) written in the form f(x)=log(1+e^{x});
Step 3: the a posteriori probabilities of bits in the main constellation M0 are expressed as a function of the a posteriori probabilities of symbols in the main constellation M0, including the soft bits in the main constellation that are output from the reconstruction of soft bits of the main modulation using a Log-Map type criterion or a Max-Log-Map type criterion, using the hard outputs of the detector used.

Furthermore, due to the simple fact that the values obtained for the bits of the symbols in the main constellation Xₖ are deterministic, it also is possible to tabulate recombination operations to optimise the method.

### Description of a Third Embodiment

### Case of Configurable Generic Detectors

In the first two embodiments of the method described above, the proposed technique is based on two main steps. The first step consists of using soft bits output from the main modulation detector (either directly in the case of a soft outputs detector, or by prior reconstruction in the case of a hard outputs detector). The second step then consists of calculating the soft bits associated with the symbols in a sub-constellation included in the main constellation, using the results of the first step.

In this third embodiment, the method no longer uses soft bits output from the detector as confidence bits, and instead uses a posteriori probabilities (APP) of symbols in the main constellation.

If a reconfigurable generic detector is used, it is easy to obtain a table of m₀ a posteriori probabilities (APP) for each symbol in the main constellation to be detected, calculated using the following algorithms:
Log-Map;
Max-Log-Map;
SOVA (Soft-Output Viterbi Algorithm) based on the maximum likelihood criterion for detection of the most probable sequence);
DDFSE (Delayed Decision Feedback Sequence Estimation);
RSSE (Reduced-State Sequence Estimation);
M-algorithm;
T-algorithm.

The next step is to calculate the soft bits of symbols in the order m₁ sub-constellation, depending on whether the algorithm is two-directional or single-directional.

Confidence bits for two-directional detection algorithms are calculated in the form of log likelihood ratios (LLR) of the sub-constellation, and this calculation then consists of the following steps as a function of the binary signal coding of this sub-constellation:
select a sub-set containing m₁ a posteriori probabilities among the m₀ available values;
define the k sub-sets Eₖ of indexes of symbols in the sub-constellation (for which the index k that depends on the binary signal coding is equal to 0) and C_{M}_{₁} (Eₖ) (complement of Eₖ in the secondary constellation);
apply the following relation to obtain the m₁ soft bits Yₖ in the form of an LLR:

$${Y}_{k} = log \frac{{\sum }_{i ∈ {E}_{k}} P ( {S}_{i} )}{{\sum }_{i ∈ {C}_{{M}_{1}} ( {E}_{k} )} P ( {S}_{i} )} \qquad ( 5 )$$

For information it can be mentioned that this relation (5) is calculated indifferently, either using the Log-Map type criterion, or using a Max-Log-Map type criterion.

For single-directional detection algorithms, the sign of the soft bits of the main modulation is obtained by a trace backing operation. Such an operation can be used to obtain information maximizing the likelihood ratio of the received sequence.

Thus, to calculate the soft bits of the sub-constellation, the soft bits of the sub-constellation are calculated as a function of the binary signal coding of the sub-constellation using the following steps:
select a sub-set containing m₁ a posteriori probabilities among the available m₀;
define k sub-sets Eₖ (indexes of symbols in the sub-constellation for which the index bit k is equal to 0) and C_{M}_{₁} (Eₖ)) (complement of Eₖ in the main constellation);
apply the following relation to obtain the m₁ soft bits Yₖ in the form of an LLR:

$${Y}_{k} = log \frac{{\sum }_{i ∈ {E}_{k}} P ( {S}_{i} )}{{\sum }_{i ∈ {C}_{{M}_{1}} ( {E}_{k} )} P ( {S}_{i} )}$$

The next step is to determine the sign of Yₖ using the step in the second embodiment mentioned above to reconstruct the soft bits of the main modulation using hard decisions output by the detector used.

### Summary of the Three Embodiments Described

Three embodiments of the method are described to demodulate signals included in a main modulation, using the main modulation detector.

The two first embodiments combine soft bits, in other words confidence bits (soft bits) generated by the main detector and do not require any modification of the hardware part of the receiving terminal and/or the detector used.

The third embodiment results in a generic hardware architecture capable of calculating soft bits of all secondary modulations of a main modulation.

For example, the method of recombining soft bits becomes particularly simple in the case of a GSM/GPRS/EDGE type receiver because it consists simply of summating two soft bits of the 8-PSK detector out of three, and then changing the sign of the result in order to obtain the soft bit associated with the GMSK modulation. In practice, the technique described makes it possible to advantageously use reception algorithms designed for EDGE, with no additional development costs applying them to demodulation of GMSK signals.

An embodiment of the invention provides a signal processing method that can be used in any receiver, to make it capable of demodulating signals output from other modulations included in a main modulation.

An embodiment implements such a method to make the signal receiver independent of the modulation to be processed and therefore avoids increasing the number of detectors within the receiver.

An embodiment further provides such a method for reusing the detector of a main constellation of symbols contained in a receiver, to demodulate the signals of the modulations included in the main constellation, the receiver then being a multi-modulation receiver.

1. Method for reception of a signal modulated according to a main constellation, called a main signal, and at least one signal modulated according to a secondary constellation, called a secondary signal, said secondary constellation being included in said main constellation, said method comprising:
demodulating said main signal, outputting a confidence bit for each of the elements in the main constellation, related to reception of said element, called a main confidence bit,
determining at least one confidence bit related to reception of at least one element of said secondary constellation, called a secondary confidence bit, using at least one of said main confidence bits, so as to demodulate the secondary signal.

2. Reception method set forth in claim 1, wherein said element is one of the bits transmitted by a symbol of said main and/or secondary constellation.

3. Reception method set forth in claim 2, wherein said main confidence bit is a hard reception decision of said bit in said main signal.

4. Reception method set forth in claim 3, wherein it comprises a prior step to determine the log likelihood ratio (LLR) of said bit called “soft bit”, for at least some of said bits of said main signal, using said associated hard decision.

5. Reception method set forth in claim 4, wherein said prior determination step uses a criterion belonging to the group comprising:
a Lop-Map criterion;
a Max-Log-Map criterion;
a SOVA (Soft-Output Viterbi Algorithm based on the maximum likelihood criterion for detection of the most probable sequence),
and/or an approximation of one of these criteria.

6. Reception method set forth in claim 2, wherein said main and/or secondary confidence bit associated with a bit is a log likelihood ratio (LLR) of said bit, called the main and/or secondary soft bit.

7. Reception method set forth in claim 6, wherein said step of determining said secondary confidence bit comprises the following sub-steps:
said secondary “soft bits” are expressed as a function of a posteriori probabilities of symbols in said secondary constellation, said symbols in said secondary constellation also belonging to said main constellation, so as to obtain a first expression;
the a posteriori probabilities of bits in said main constellation are expressed as a function of the a posteriori probabilities of symbols in said main constellation, bringing out the soft bits of said main constellation, output during said demodulation step of said main signal so as to obtain a second expression.

8. Reception method set forth in claim 7, wherein it also comprises a sub-step of mathematically simplifying said first expression, using a saturated linear approximation or a piecewise linear approximation.

9. Reception method set forth in claim 7 wherein it also comprises a sub-step to classify symbols in said main constellation so as to minimise the number of soft bits in said main constellation used during the calculation of soft bits in said secondary constellation.

10. Reception method set forth in claim 1, wherein the element is a symbol in said main and/or secondary constellation.

11. Reception method set forth in claim 10, wherein said main and/or secondary confidence bit associated with a symbol is an a posteriori probability of a symbol in said main and/or secondary constellation.

12. Reception method set forth in claim 11, wherein during said step of demodulating said main signal, said main confidence bits are calculated using one of the detection algorithms belonging to the group comprising:
a Max-Log-Map;
a Log-Map;
SOVA (Soft-Output Viterbi Algorithm based on the maximum likelihood criterion for detection of the most probable sequence);
DDFSE (Delayed Decision Feedback Sequence Estimation);
RSSE (Reduced-State Sequence Estimation);
M-algorithm;
T-algorithm.

13. Reception method set forth in claim 12, wherein said detection algorithm being two-directional, said secondary confidence bits associated with the symbols in said secondary constellation are secondary soft bits corresponding to the log likelihood ratio (LLR) values of said bits of said symbols, and are determined by the following sub-steps:
selecting a sub-set of a posteriori probabilities of symbols in said secondary constellation among the set of a posteriori probabilities of available symbols in said main constellation;
determining said secondary soft bits as a function of said sub-set of a posteriori probabilities of symbols in said secondary constellation, said symbols in said secondary constellation also belonging to said main constellation.

14. Reception method set forth in claim 13, wherein said sub-step of determining uses a criterion belonging to the following group:
the Log-Map criterion;
the Max-Log-Map criterion;
SOVA (Soft-Output Viterbi Algorithm based on the maximum likelihood criterion for detection of the most probable sequence),
and/or approximation of one of these criteria.

15. Reception method set forth in claim 12, wherein since said detection algorithm is single-directional, said secondary confidence bits associated with symbols in said secondary constellation are secondary soft bits corresponding to the log likelihood ratio (LLR) values of said bits of said symbols, and are determined by the following sub-steps:
selecting a sub-set of a posteriori probabilities of symbols in said secondary constellation among the set of a posteriori probabilities of available symbols in said main constellation;
determining said secondary soft bits as a function of the sub-set of a posteriori probabilities of symbols in said secondary constellation, said symbols in said secondary constellation also belonging to said main constellation;
determining the sign of secondary soft bits as a function of the value of bits of symbols in said main constellation.

16. Reception method as claimed in claim 1, wherein said main and/or secondary constellations belong to the group comprising:
M-QAM modulations, where M=2m;
N-PSK modulations, where N=2n;
a linearised GMSK or MSK modulation.

17. Receiver of a modulated signal according to a main constellation, called a main signal, and at least one modulated signal according to a secondary constellation, called a secondary signal, said secondary constellation being included in said main constellation, said receiver comprising:
a demodulator, which demodulates said main signal outputting a confidence bit related to reception of each element in the main constellation, called a main confidence bit, and determining at least one confidence bit related to reception of at least one element in said secondary constellation, called a secondary confidence bit, using at least one of said main confidence bits, so as to demodulate the secondary signal.

18. Receiver set forth in claim 17, wherein this receiver is of the type belonging to the group comprising:
GSM receivers;
GPRS receivers;
EDGE receivers.

19. Receiver set forth in claim 17, wherein said element is one of the bits transmitted by a symbol in said main and/or secondary constellation.

20. Receiver set forth in claim 19, wherein said main confidence bit is comprises a hard decision for reception of said bit in said main signal, and wherein the demodulator determines the log likelihood ratio (LLR) of said bit called a “soft bit”, for at least some of said bits of said main signal, using said associated hard decision.

21. Receiver set forth in claim 20, wherein the demodulator determines the log likelihood ratio (LLR) using a criterion belonging to the group comprising:
a Lop-Map criterion;
a Max-Log-Map criterion;
a SOVA (Soft-Output Viterbi Algorithm based on the maximum likelihood criterion for detection of the most probable sequence);
and/or approximation of one of these criteria.

22. Receiver set forth in claim 17, wherein the main and/or secondary confidence bit associated with a bit is a log likelihood ratio (LLR) of said bit, called a main and/or secondary soft bit, and said demodulator, which determines said secondary confidence bit comprises additional outputs:
to express the secondary “soft bits” as a function of a posteriori probabilities of symbols in said secondary constellation, said symbols in said secondary constellation also belonging to said main constellation, so as to obtain a first expression;
to express a posteriori probabilities of bits in said main constellation as a function of the a posteriori probabilities of symbols in said main constellation, bringing out the soft bits in said main constellation, output during said demodulation step of said main signal so as to obtain a second expression.

23. Receiver set forth in claim 17, wherein said element is a symbol in said main and/or secondary constellation.

24. Receiver set forth in claim 23, wherein said main and/or secondary confidence bit associated with a symbol comprises an a posteriori probability of a symbol in said main and/or secondary constellation, and in that said demodulator, which demodulates said main signal uses one of the detection algorithms belonging to the group comprising to calculate said main confidence bits:
a Max-Log-Map;
a Log-Map;
SOVA (Soft-Output Viterbi Algorithm based on the maximum likelihood criterion for detection of a most probable sequence);
DDFSE (Delayed Decision Feedback Sequence Estimation);
RSSE (Reduced-State Sequence Estimation);
M-algorithm;
T-algorithm;
to calculate said main confidence bits.

25. Receiver as set forth in claim 17, wherein said main and/or secondary constellations belong the group comprising:
M-QAM modulations, where M=2m;
N-PSK modulations, where N=2n;
a linearised GMSK or MSK modulation.
